(19) United States
(12) Patent Application Publication
(10) Pub. No.: US 2011/0031503 A1
(43) Pub. Date: Feb. 10, 2011

(54) DEVICE WITH STRESSED CHANNEL

(75) Inventors: Bruce B. Doris, Brewster, NY (US); Johnathan E. Faltermeier, Delanson, NY (US); Lahir S. Adam, Wappingers Falls, NY (US); Balasubramanian S. Haran, Watervliet, NY (US)

Correspondence Address: INNOVATION INTERFACE, LLC, 200 Roger Williams Ave, Suite 415, Rumford, RI, 02916, US

(73) Assignee: International Business Machines Corporation, Armonk, NY (US)

(21) Appl. No.: 12/538,627

(22) Filed: Aug. 10, 2009

(51) Int. Cl. H01L 29/161; H01L 27/092; H01L 21/04; H01L 21/8238

(52) U.S. Cl. 257/77; 438/285; 438/199; 257/E29.084; 257/E27.062; 257/E21.066; 257/E21.632

(57) ABSTRACT

An FET device is disclosed which contains a source and a drain that are each provided with an extension. The source and the drain, and their extensions, are composed of epitaxial materials containing Ge or C. The epitaxial materials and the Si substrate have differing lattice constants, consequently the source and the drain and their extensions are imparting a state of stress onto the channel. For a PFET device the epitaxial material may be SiGe, or Ge, and the channel may be in a compressive state of stress. For an NFET device the epitaxial material may be SiC and the channel may be in a tensile state of stress. A method for fabricating an FET device is also disclosed. One may form a first recession in the Si substrate to a first depth on opposing sides of the gate. The first recession is filled epitaxially with a first epitaxial material. Then, a second recession may be formed in the Si substrate to a second depth, which is greater than the first depth. Next, one may fill the second recession with a second epitaxial material, which is the same kind of material as the first epitaxial material. The epitaxial materials are selected to have a different lattice constant than the Si substrate, and consequently a state of stress is being imparted onto the channel.

### BACKGROUND

The present invention relates to electronic devices. In particular, it relates to FET devices in which the channel is in a state of stress.

Today's integrated circuits include a vast number of devices. As FET (Field-Effect-Transistor) devices are being scaled down, the technology becomes more complex, and changes in device structures and new fabrication methods are needed to maintain the expected performance enhancement. Device performance may be enhanced by introducing appropriate stress into the device channel, and thereby increase carrier mobility.

### BRIEF SUMMARY

An FET device is disclosed, which FET contains a source and a drain that are each provided with an extension. The FET device is located at a surface of a Si substrate, and the source/drain extensions are mutually connected through the device channel, while respectively extending at the surface from the source and the drain towards the channel. The source and the drain, and their extensions, are composed of epitaxial materials containing Ge or C. The epitaxial materials and the Si substrate have differing lattice constants. Due to this lattice constant difference the source and the drain and their extensions are imparting a state of stress onto the channel. For a PFET device the epitaxial materials may be of SiGe, or Ge, and the channel may be in a compressive state of stress. For an NFET device the epitaxial materials may be of SiC and the channel may be in a tensile state of stress.

A method for fabricating an FET device is also disclosed. In the method one provides for a channel at a surface of a Si substrate and for overlapping the channel with a gate. One may form a first recession in the Si substrate to a first depth on opposing sides of the gate. Laterally, this first recession reaches the channel on both of the opposing sides of the gate. The first recession is filled epitaxially with a first epitaxial material. One then may form a second recession in the Si substrate to a second depth on opposing sides of the gate. The second depth is greater than the first depth, and laterally the second recession is spaced away from the channel by a spacer on both opposing sides of the gate. Next, one may fill epitaxially the second recession with a second epitaxial material, which is the same kind of material as the first epitaxial material. The epitaxial materials are selected to have a different lattice constant than the Si substrate, and consequently a state of stress is being imparted onto the channel.

### BRIEF DESCRIPTION OF THE SEVERAL VIEWS OF THE DRAWINGS

These and other features of the present invention will become apparent from the accompanying detailed description and drawings, wherein:

FIG. 1 shows a schematic cross section of a stressed channel FET device with epitaxial source/drain and epitaxial extensions;

FIG. 2 shows a schematic cross section of a circuit structure with NFET and PFET devices having oppositely stressed channels;

FIG. 3A to 3E show steps of an embodiment of the method for creating stress in the channel by epitaxial source/drain and epitaxial extensions; and

FIG. 4A and 4B show a masking scheme for fabricating a circuit structure with NFET and PFET devices having oppositely stressed channels.

### DETAILED DESCRIPTION

It is understood that Field Effect Transistor-s (FET) are well known in the electronic arts. Standard components of a FET are the source, the drain, the body in-between the source and the drain, and the gate. The gate is overlaying the body and is capable to induce a conducting channel in the body between the source and the drain. In the usual nomenclature, the channel is hosted by the body, and the FET device is at a surface of a substrate. In advanced, deeply submicron devices, the source and drain are augmented by extensions. These extensions are shallower than the source and drain, and typically contact the channel at the gate edge. The gate is typically separated from the body by the gate insulator. Depending whether the “on state” current in the channel is carried by electrons or holes, the FET comes as NFET or PFET. (In different nomenclature the NFET and PFET devices are often referred to as NMOS and PMOS devices.) It is also understood that frequently the NFET and PFET devices are used together in circuits. Such NPET PFET combination circuits may find application in analogue circuits, or in digital circuits where they are typically coupled into CMOS configurations.

Manufacturing of NFET, PFET, and CMOS is very well established in the art. It is understood that there are large number of steps involved in such processing, and each step may have practically endless variations, known to those skilled in the art. For embodiment of this disclosure it is understood that the whole range of known processing techniques are available for fabricating the devices, and only those process steps will be detailed that are related to the embodiments of the present invention.

The most common material of microelectronics is silicon (Si), or more broadly, Si based materials. Si based materials are various alloys of Si in the same basic technological content as Si. Such Si based materials of significance for microelectronics are, for instance, the alloys of Si with other elements of the IV-th group of the periodic table, Group IV elements for brevity. Such alloys formed with Ge and C are silicon germanium (SiGe), and silicon carbon (SiC). Essentially pure Ge itself may play a role in Si based microelectronics. The devices in the embodiments of the present disclosure are typically part of the art of single crystal Si, and of epitaxial art involving, besides Si, Ge or C.

In advanced, deeply submicron devices, in the below 50 nm gate length regime, keeping carrier mobility as high as possible is one of the challenges. Improving channel mobility is one of the main methods of improving device performance. It has been known in the art that stress in the channel influences carrier mobility.

For uniaxial stress, electron mobility in NFET devices with a (100) surface orientation may increase when the channel is under tensile stress either in the longitudinal, or in the transverse direction. Longitudinal direction is defined as the direction of the current flow from source to drain, and transverse direction is defined as the direction perpendicular to the device current flow. Hole mobility in PFET devices, on the other hand, may improve in (100) surface oriented Si for compressive stress in the longitudinal direction in the channel.

It has been demonstrated that a source and drain under compressive state of stress imparts a compressive stress onto the channel. Similarly, it has been demonstrated that a source and drain under tensile state of stress imparts a tensile stress onto the channel. See, for instance, S. Thompson et al., IEDM 2006, pp. 681-684. In general, the higher the state of correct stress type in the channel, the higher is the carrier mobility. Accordingly, one would desire to achieve the highest possible state of stress in the channel while keeping processing of the devices simple, and, possibly, in circuit structures where there are both NFET and PFET devices, to impart the proper kind of stress for both type of devices.

One way to create a stress is to epitaxially deposit a material into a host material, when the lattice constant of the deposited material is different than that of the host material. In describing a structure, the adjective “epitaxial” is typically used to indicate if a particular material has been epitaxially deposited. The structural consequence of epitaxial deposition is that the deposited material and the host material have the same symmetry and crystalline orientation. Further terms that may be used, such as “epitaxial relation”, “epitaxially”, “epitaxy”, “epi”, “epitaxial growth” etc. carry their customary usage: meaning, again, that a material is formed in a host, which material has the same symmetry and crystalline orientation as the host itself. If the lattice constant of the epitaxially deposited material and that of the host differ, stress arises in the deposited material and in the portion of the host which surrounds the material. Along a major interface of the deposited material and the host material, if the lattice constant of the epitaxial material is larger than that of the host, then the epitaxial material is in a compressive state of stress, and conversely, if the lattice constant of the epitaxial material is smaller than that of the host, then the epitaxial material is in a tensile state of stress.

The lattice constant of germanium (Ge) is about 4.2% greater than that of silicon, and the lattice constant of a silicon-germanium alloy is roughly a linear function of its germanium concentration. As a result, for instance, the lattice constant of a SiGe alloy containing fifty atomic percent germanium is about 2% greater than the lattice constant of silicon. The carbon atom is smaller than the silicon atom, consequently, when C is incorporated into the Si lattice, the resulting lattice constant of SiC is smaller than that of Si. For relatively low C concentrations, below about 20%, the lattice constant of SiC is decreasing nearly linearly with the C concentration.

Resulting from the lattice constant relations of Si, Ge, and C, if an epitaxial source/drain of a Si FET contains Ge, a compressive stress will be imparted onto the channel. And, conversely, if an epitaxial source/drain of a Si FET contains C, a tensile stress will be imparted onto the channel. For instance, see again, S. Thompson et al., IEDM 2006, pp. 681-684.

The amount of stress imparted by a stressed material, onto the material which is imbedding it, decreases with increasing distance from the stressed material. Also, the amount of the stressed material correlates as to what degree stress is imparted onto the imbedding material. For stressing the channel, it is desirable to bring the stress as near to the channel as possible, and to have a relatively large stressed region in the neighborhood of the channel, as well. Embodiments of this disclosure teach the stressing of FET device channel by creating a source/drain, as well as, source/drain extensions that are appropriately stressed for each type of device.

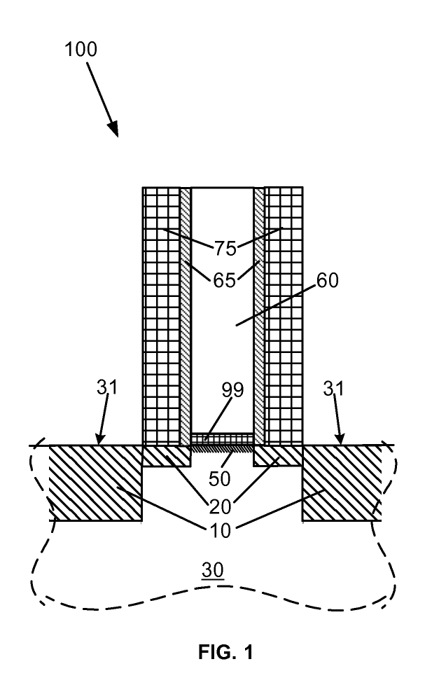

FIG. 1 shows a schematic cross section of a stressed channel FET device 100 with epitaxial source/drain and epitaxial extensions. The displayed FET 100 may be either an NFET, or a PFET. The figure shows a Si substrate 30 having a surface 31, which may also be regarded as a primary surface plane defining the positions of the FET and its various parts. The FET device 100 is provided at the surface 31 of the Si substrate 30. The substrate 30 may be any type known in the electronic art, such as bulk, or semiconductor on insulator (SOI), fully depleted, or partially depleted, or any other kind. The figure shows what typically may be only a small fraction of an electronic chip, for instance a processor, as indicated by the wavy dashed line boundaries. The FET 100 has a gate 60, often also referred to as gate stack, and a gate insulator 99. Again, both the gate 60 and the gate insulator 99 may be any kind known in the art without restriction. The device channel 50 is essentially at the substrate surface 31, as part of the substrate 30, or more generally, as part of the device body. There are many known manners of substrate engineering, such as depositing various semiconductor layers onto the substrate, which are all included without limitation within the embodiments of the present invention. The channel 50 is induced to turn conductive upon the application of a proper voltage on the gate 60.

FIG. 1 also shows a source and a drain 10 that are each provided with an extension 20. The extensions 20 are mutually connected through the channel 50, while respectively extending at the surface 31 from the source and drain 10 towards the channel 50. In embodiments of the present invention both the source/drain 10 and the extensions 20 are epitaxial, meaning that they have the same symmetry and crystalline orientation as the substrate 30 itself, but they were not originally parts of the substrate; they were purposefully deposited in an epitaxial process. The extensions 20 are of a first epitaxial material, and the source/drain 10 are of a second epitaxial material. The material of the epitaxial source and drain 10 and that of the extensions 20 may contain Si, and the Group IV elements of C or Ge. The Si substrate 30, and the epitaxial materials that compose the source/drain 10 and the extensions 20, have differing lattice constants. As a consequence of this difference in lattice constants, the source and the drain 10 and the extensions 20 are imparting a state of stress onto the channel 50.

While the epitaxial material in the source and drain 10 and in the extensions 20 is the same kind of material, the exact composition of the extensions 20 may, or may not, match that of the source and drain 10.

The gate 60 usually has various constructs in its sidewalls, for instance, spacers 75. Spacers are well known in the electronic arts. They serve as a protection for the gate, and to space away the sauce and drain 10 from the channel. Further construct on the gate sidewalls may be the offset spacers 65. As known in the art, offset spacers 65 may fill a similar role for source/drain extensions 20 and halo implants as the regular spacers fulfill in respect to the source/drain junctions 10. Also, the offset spaces are often used to chemically protect the gate during various processing steps, for instance etching. If both spacers 75 and offset spacers 65 are present in the processed FET, then, typically, the offset spacers 65 are sandwiched inbetween the gate 60 and the spacers 75.

When the FET device shown in FIG. 1 is a PFET device, the epitaxial material of the of the source and drain 10 and the extensions 20 may be SiGe, or essentially 100% Ge. As a result of this selection the state of stress in the channel is a compressive state of stress. For PFET devices the hole mobility increases with compressive stress in the channel. In embodiments of the invention the Ge content in the extensions 20 may be between 5% and 100%, more typically between 15% and 45%.

In some embodiments of the invention the Ge content is the same in the extensions 20 and in the source and drain 10. However, this is not necessarily the case, as embodiments of the present invention allow for differing Ge content for the extensions 20 and for the source/drain 10. Depending on the detailed dimensions of the device, and possibly on the desired function and performance of the device, it may be advantageous to further tailor the compressive stress in the channel by varying the Ge content of the extensions 20 relative to that of the source/drain 10. In some embodiments of the invention the extensions 20 may have a higher Ge content than the source/drain 10.

When the FET device shown in FIG. 1 is a NFET device, the epitaxial material of the of the source and drain 10 and the extensions 20 may be SiC. As a result of this selection the state of stress in the channel is a tensile state of stress. For NFET devices the electron mobility increases with tensile stress in the channel. In embodiments of the invention the SiC in the extensions 20 has a C content of between 0.1% and 20%, more typically between 0.5% and 2.5%.

In some embodiments of the invention the C content of the SiC is the same in the extensions 20 and in the source and drain 10. However, this is not necessarily the case, as embodiments of the present invention allow for differing C content for the extensions 20 and for the source/drain 10. Depending on the detailed dimensions of the device, and possibly on the desired function and performance of the device, it may be advantageous to further tailor the tensile stress in the channel by varying the C content of the extensions 20 relative to that of the source/drain 10. In some embodiments of the invention the extensions 20 may have a higher C content than the source/drain 10.

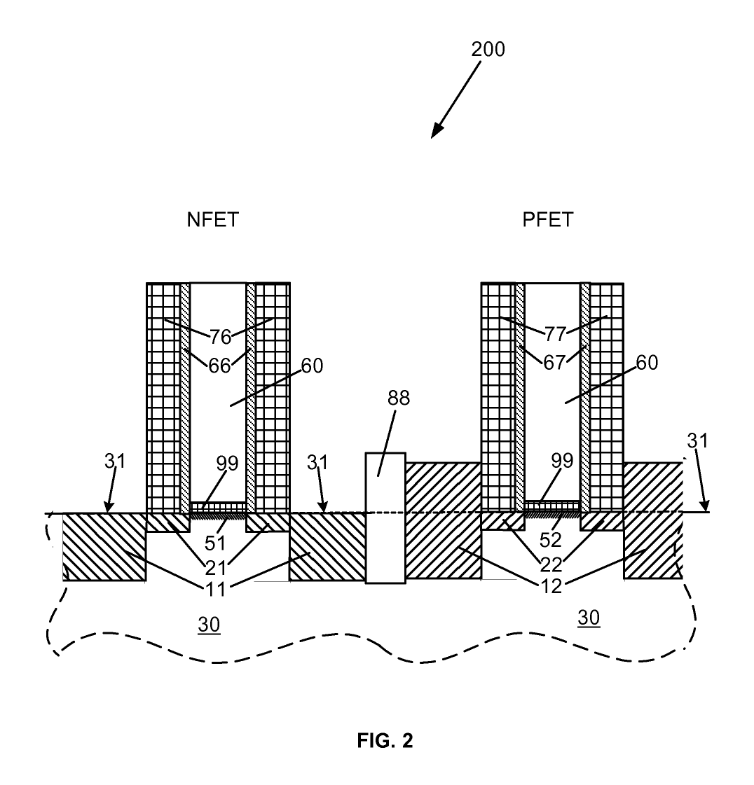

FIG. 2 shows a schematic cross section of a circuit structure 200 with NFET and PFET devices having oppositely stressed channels. Embodiments of the invention allow for both NFET and PFET fabrication on the same Si substrate, with each type of device having their channels in an appropriate state of stress, due to their epitaxial source/drain and epitaxial extensions.

The figure shows at least one NFET portion and at least one PFET portion at a surface 31 of a Si substrate 30. The Si substrate 30 may be any type known in the electronic art, such as bulk, or semiconductor on insulator (SOI), fully depleted, or partially depleted, or any other kind. The figure shows what typically may be only a small fraction of an electronic chip, for instance a processor, as indicated by the wavy dashed line boundaries. Both type of devices have a gate 60, often called gate stack, as well, and a gate insulator 99. Again, both the gate 60 and the gate insulator 99 may be any kind known in the art without restriction. Generally there are differences between the gates of the NFET and PFET and the same is true for the gate insulators. However, for the embodiments of the present disclosure such differences are of no particular interest, and they may be treated as generic gates and gate insulators, having non-distinguishing indicator numbers.

FIG. 2 indicates that essentially at the substrate surface 31 there is the NFET device having an n-channel 51. The n-channel 51 is induced to turn conductive upon the application of a proper voltage on the gate 60. FIG. 2 also shows an n-source and an n-drain 11 that are each provided with an n-extension 21. The n-extensions 21 are mutually connected through the n-channel 51, while respectively extending at the surface 31 from the n-source and n-drain 11 towards the n-channel 51. In embodiments of the present invention both the n-source/drain 11 and the n-extensions 21 are epitaxial, meaning that they have same symmetry and crystalline orientation as the substrate 30 itself, but they were not originally parts of the substrate; they were purposefully deposited in an epitaxial process. The material of the epitaxial n-source and n-drain 11 and the n-extensions 21 may be SiC. The SiC of the n-source and n-drain 11 and the n-extensions 21, has a smaller lattice constants than the Si substrate. As a consequence, the n-source and the n-drain 11 and the n-extensions 21 are imparting a tensile state of stress onto the n-channel 51.

In some embodiments of the invention the C content of the SiC is the same in the n-extensions 21 and in the n-source and n-drain 11. However, this is not necessarily the case, as embodiments of the present invention allow for differing C content for the n-extensions 21 and for the n-source/drain 11.

The NFET gate 60 usually has various constructs in its sidewalls, for instance, n-offset spacers 66 and n-spacers 76. The role of such spacers was already discussed in relation to FIG. 1.

FIG. 2 also shows that essentially at the substrate surface 31 there is the PFET device having a p-channel 52. The p-channel 52 is induced to turn conductive upon the application of a proper voltage on the gate 60. FIG. 2 also shows an p-source and an p-drain 12 that are each provided with an p-extension 22. The p-extensions 22 are mutually connected through the p-channel 52, while respectively extending at the surface 31 from the p-source and p-drain 12 towards the p-channel 52. In embodiments of the present invention both the p-source/drain 12 and the p-extensions 22 are epitaxial, meaning that they have same symmetry and crystalline orientation as the substrate 30 itself, but they were not originally parts of the substrate; they were purposefully deposited in an epitaxial process. The material of the epitaxial p-source and p-drain 12 and the p-extensions 22 may be SiGe, or may be essentially 100% Ge. The epitaxial material of the p-source and p-drain 12 and the p-extensions 22, has a larger lattice constants than the Si substrate. As a consequence, the p-source and the p-drain 12 and the p-extensions 22 are imparting a compressive state of stress onto the p-channel 52.

In some embodiments of the invention the Ge content is the same in the p-extensions 22 and in the p-source and p-drain 12. However, this is not necessarily the case, as embodiments of the present invention allow for differing C content for the p-extensions 22 and for the p-source/drain 12.

The PFET gate 60 usually has various constructs in its sidewalls, for instance, p-offset spacers 67 and p-spacers 77. The role of such spacers was already discussed in relation to FIG. 1.

FIG. 2 further shows other typical elements in the circuits structures 200 of the embodiments. The NFET and PFET portions on the substrate are usually isolated from one another, for instance, by shallow trenches 88. Such shallow trenches 88 are a typical advanced isolation technique available in the electronics processing art, but their presence is not necessary for embodiments of the present invention. Any type of isolation would be acceptable. As the figure shows, the trench 88 may protrude out of the Si substrate 30 to above the substrate surface 31. For the PFET, FIG. 2 further illustrates that in a typical embodiment the source/drain 12 may be raised to a level above the substrate surface 31. Advantages for such raised source/drain are known in the art. In embodiments of the present invention such source/drain raising may, or may not, be present, for one, or both type of devices. Any such, so called source/drain engineering, does not limit the embodiments of the present invention.

In a typical embodiment of the disclosure the circuit structure 200, is, or it is wired, or fabricated into, a CMOS structure.

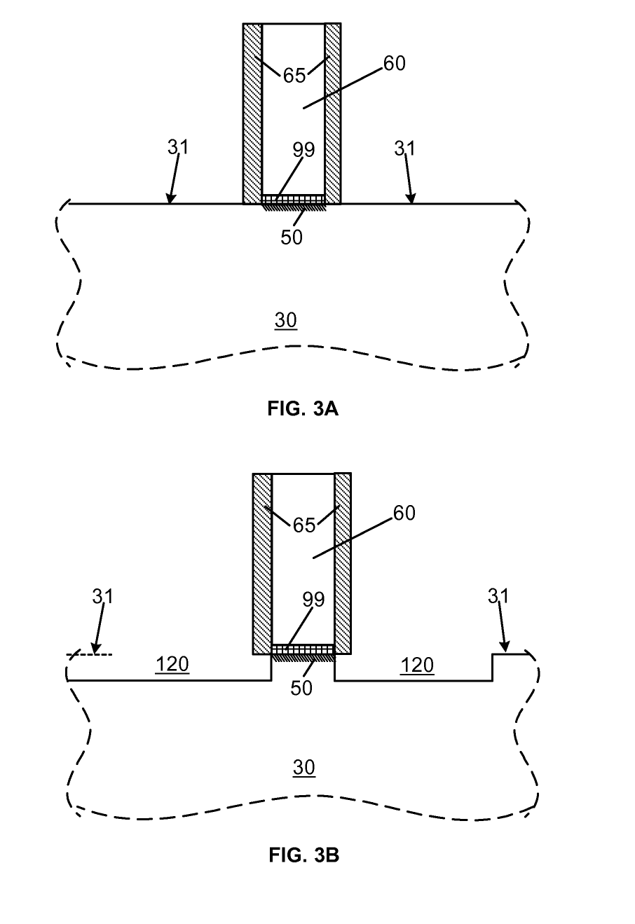

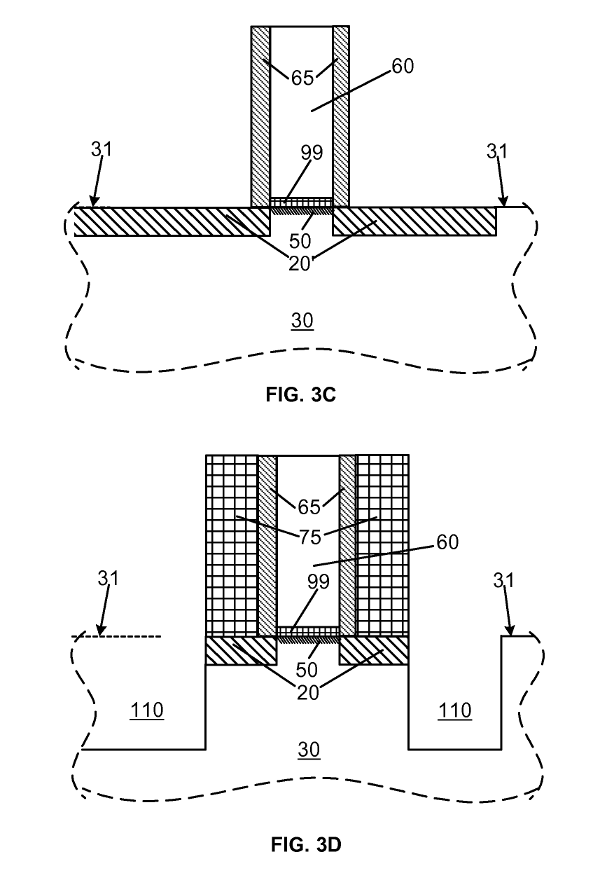

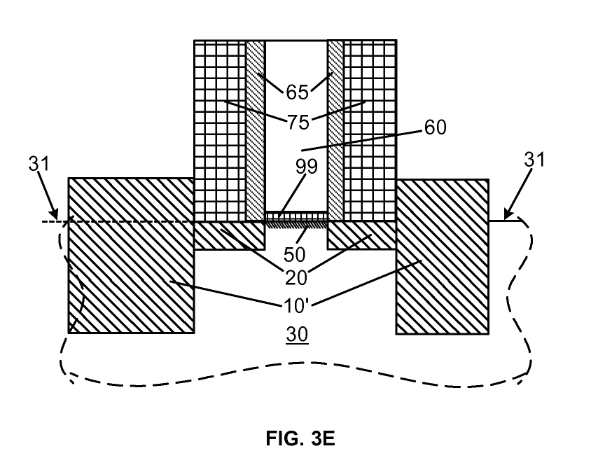

FIGS. 3A to 3E show steps of an embodiment of the method for creating stress in the channel by epitaxial source/drain and epitaxial extensions. This method in the figures is illustrated for a generic device, as the one shown in FIG. 1. The fabrication for both the NFET and PFET devices is essentially the same, with obvious substitutions of “n” and “p” for structures and/or for carriers. FIG. 1A shows the Si substrate 30 including the surface 31, and a fabricated gate 60 and gate insulator 99. The gate 60 is adapted to induce a conductive channel under the gate insulator 99. The gate 60 is provided with offset sidewalls 65. Up to this point the processing may follow standard, known in the art, FET, typically CMOS, processing.

FIG. 3B shows the state of processing after a first recession 120 has been etched out in the Si substrate 30 on opposing sides of the gate 90. There are several etches known in the art that may be adequate for this purpose, such as, for instance a HBr plasma etch. The first recession 120 reaches a first depth, while laterally the first recession 120 essentially reaches the channel on both opposing sides of the gate 60. The offset spacers 65 typically protect the gate 60 during the etching process. The figure also schematically illustrates the potential presence of an isolation structure, which limits the extent of the device, by showing an abrupt ending to the first recession 120 on the right hand side of the figure.

FIG. 3C shows the state of processing after the first recession has been filled epitaxially with a first epitaxial material 20′, which may be SiGe, or Ge, for the PFET, and SiC for the NFET. There are many knows processes for epitaxially depositing a Group IV materials, such as, without limitation, MBE, CVD, LPCVD, and others. A preferred process for embodiments of the present invention may be LPCVD (Low Pressure Chemical Vapor Deposition) for SiGe or Ge, and for SiC. All of the epitaxial deposition referred to and discussed for embodiments of the present disclosure are done in a selective manner. Such selective processes are known in the art. The first epitaxial material 20′ essentially fills the first opening 120 up to the substrate surface 31. The offset spacers 65 typically protect the gate 60 during the epitaxial deposition process, and prevent deposition onto the sides of the gate. The portion reaching toward the channel of the first epitaxial material 20′ deposited into the first opening 120, will be the epitaxial source/drain extension 20 of the completed device. The detailed composition of either the Ge or the C have already been discussed in reference to FIG. 1.

FIG. 3D shows the state of processing after spacers 75 have been provided over the gate sidewalls, and a second recession 110 has been formed in the Si substrate 30. The second recession 120 reaches to a second depth on opposing sides of the gate 60. The second depth of the second recession 110 is greater than the first depth of the first recession 120. While, laterally the second recession 120 is spaced away from the channel by the spacer 75 on both opposing sides of the gate 60.

FIG. 3D shows the state of processing after filling epitaxially the second recession 110 with a second epitaxial material 10′. This second epitaxial material 10′ is the same kind of material as the first epitaxial material 20′. This second epitaxial material 10′ may be SiGe, or Ge, for the PFET, and SiC for the NFET. When the device is fully processed, the second epitaxial material 10′ deposited into the second recession 110, will become the epitaxial source/drain 10 of the device. This figure also shows a case when the epitaxial deposition into the second recession 110 is such that it protrudes above the substrate surface 31 to form a raised source/drain 10.

The FET devices in representative embodiments of the present invention may gave gate lengths below 40 nm, possibly below 10 nm. The depth of the first recession 120 may be in the range of 2 nm to 25 nm, while the depth of the second recession 110 may be in the range of 20 nm to 100 nm. The width of the spacers 75, which is approximately the same as the length of the extensions 20 from the source/drain 10 till the channel 50, may be between 5 nm and 50 nm.

Following the deposition into the second recession 110 of the second epitaxial material 10′, the processing related to the embodiments of the present invention has essentially been completed. From hence forward one may continue with FET fabrication as known in the art.

As discussed above, in representative embodiments of the invention there are two separate epitaxial deposition steps, namely when filling the first recession 120 with a first epitaxial material 20′ containing C or Ge, and when filling the second recession 110 with a second epitaxial material 10′, which is the same kind material as the first epitaxial material 20′. Since there are two separate deposition, one has the option, if so desired, to vary the Ge or the C content between the source/drain and the extensions for either, or both, the PFET and the NFET respectively.

Since the source/drain and the extensions are epitaxially deposited, one has the option of insitu doping these device components. For the NFET the n-source/drain 11 and the n-extension 21 may be in insitu doped with As and/or P, while for the PFET, B may be a preferred dopant. Advantages for insitu doping are known in the art.

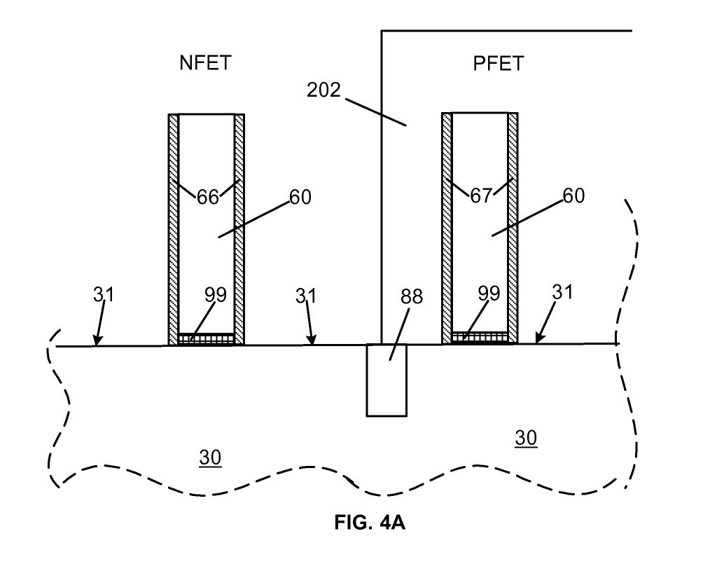

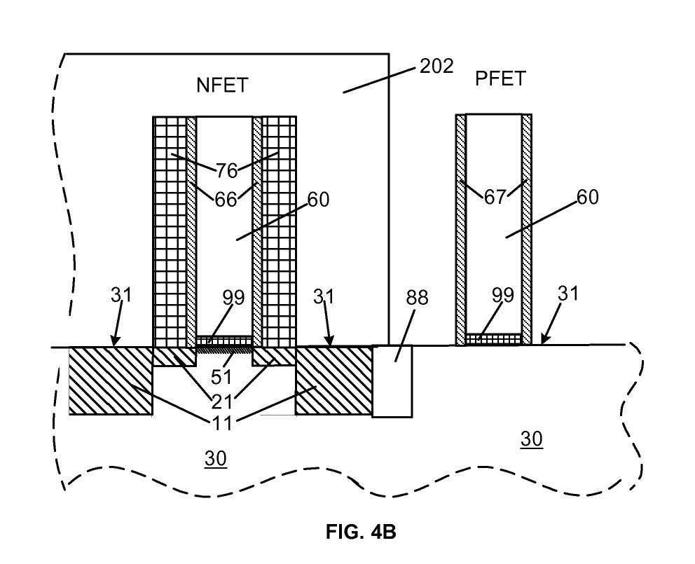

FIG. 4A and 4B show a masking scheme for fabricating a circuit structure with NFET and PFET devices having oppositely stressed channels. When fabricating circuit structures with both NFET and PFET devices, such as CMOS structures, embodiments of the present invention employ masking. A possible scheme for such masking is shown in FIGS. 4A and 4B. FIG. 4A shows that up to the point of having to etch the first recession, both the NFET and the PFET devices in their respective portion of the Si substrate, have been completed in ways known in the art. At this point the PFET portion of the circuit structure is covered by a mask 202, which may typically be a so called hard mask. With the PFET portion masked, the processing proceeds on the NFET portion as described in reference to FIGS. 3A to 3E. When this is completed, the mask is removed from the PFET portion, and the NFET portion is masked 202, as shown in FIG. 4B. Now the PFET portion processing may proceed as described in reference to FIGS. 3A to 3E.

The sequence of masking may be exchanged, meaning first the NFET portions would be masked, and the PFET portion masking would follow after the proper fabrication steps on the PFET portions have been completed.

Dealing with masking as depicted in FIG. 4A and 4B may possibly be the most seamless inclusion of epitaxially depositing SiGe and SiC source/drain and extensions, as taught by embodiments of the present invention, into a standard CMOS processing. However, if the need arises, NFET or PFET portions may be masked at a different stages of process. For instance, one portion or the other may be masked before any structure, for instance, the gate has been fabricated. Embodiments of the present disclosure are not limited by what kind of masking is used, or at what point in the fabrication process is the masking applied.

In the foregoing specification, the invention has been described with reference to specific embodiments. However, one of ordinary skill in the art appreciates that various modifications and changes can be made without departing from the scope of the present invention as set forth in the claims below. Accordingly, the specification and figures are to be regarded in an illustrative rather than a restrictive sense, and all such modifications are intended to be included within the scope of present invention.

In addition, any specified material or any specified dimension of any structure described herein is by way of example only. Furthermore, as will be understood by those skilled in the art, the structures described herein may be made or used in the same way regardless of their position and orientation. Accordingly, it is to be understood that terms and phrases such as “under,” “top”, “side,” “on”, “protruding” etc., as used herein refer to relative location and orientation of various portions of the structures with respect to one another, and are not intended to suggest that any particular absolute orientation with respect to external objects is necessary or required.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature, or element, of any or all the claims.

Many modifications and variations of the present invention are possible in light of the above teachings, and could be apparent for those skilled in the art. The scope of the invention is defined by the appended claims.

1. An FET device, comprising:
a source and a drain that are each provided with an extension, wherein said FET device is provided at a surface of a Si substrate, wherein said extensions are mutually connected through a channel while respectively extending at said surface from said source and said drain towards said channel, wherein said extensions are of a first epitaxial material and said source and said drain are of a second epitaxial material, wherein said first and said second epitaxial materials each have a separate content of a same Group IV element, which Group IV element is C or Ge, resulting in a lattice constant difference between said Si substrate and said first and said second epitaxial materials, wherein said source and said drain and said extensions are imparting a state of stress onto said channel due to said lattice constant difference.

2. The FET device of claim 1, wherein said FET device is a PFET device, wherein said same Group IV element is Ge, and wherein said state of stress is a compressive state of stress.

3. The FET device of claim 2, wherein said first epitaxial material has a Si content of between 0% and 95%, and correspondingly a Ge content is between 100% and 5%.

4. The FET device of claim 3, wherein said Ge content in said first epitaxial material is different than a Ge content in said second epitaxial material.

5. The FET device of claim 1, wherein said FET device is an NFET device, wherein said first and said second epitaxial materials are SiC, and wherein said state of stress is a tensile state of stress.

6. The FET device of claim 5, wherein said SiC in said first epitaxial material has a C content of between 0.1% and 20%.

7. The FET device of claim 6, wherein said C content in said first epitaxial material is different than a C content in said second epitaxial material.

8. A circuit structure, comprising:
at least one NFET device, said NFET device comprises an n-source and an n-drain that are each provided with an n-extension, wherein said NFET device is provided in an NFET portion at a surface of a Si substrate, wherein said n-extensions are mutually connected through an n-channel and respectively extend at said surface from said n-source and said n-drain towards said n-channel, wherein said n-source and said n-drain and said n-extensions are composed of SiC having a smaller lattice constant than said Si substrate, whereby due to said smaller lattice constant said n-source and said n-drain and said n-extensions are imparting a tensile state of stress onto said n-channel; and
at least one PFET device, said PFET device comprises a p-source and a p-drain that are each provided with a p-extension, wherein said PFET device is provided in a PFET portion at said surface of said Si substrate, wherein said p-extensions are mutually connected through a p-channel and respectively extend at said surface from said p-source and said p-drain towards said p-channel, wherein said p-source and said p-drain and said p-extensions each contain Ge, whereby having a larger lattice constant than said Si substrate, and due to said larger lattice constant said p-source and said p-drain and said p-extensions are imparting a compressive state of stress onto said p-channel.

9. The circuit structure of claim 8, wherein said p-extensions have a Si content of between 0% and 95%, and correspondingly a Ge content between 100% and 5%.

10. The circuit structure of claim 9, wherein said Ge content in said p-extensions is different than a Ge content in said p-source and said p-drain.

11. The circuit structure of claim 8, wherein in said n-extensions said SiC has a C content of between 0.1% and 20%.

12. The circuit structure of claim 11, wherein said C content in said n-extensions is different than a C content in said n-source and said n-drain.

13. The circuit structure of claim 8, wherein said circuit structure is characterized as being a CMOS structure.

14. A method for fabricating an FET device, comprising:
providing for a channel at a surface of a Si substrate, and overlapping said channel with a gate, wherein said gate has sidewalls;
forming a first recession in said Si substrate to a first depth on opposing sides of said gate, wherein laterally said first recession reaches said channel on both said opposing sides of said gate;
filling said first recession with a first epitaxial material;
providing a spacer over said sidewalls;
forming a second recession in said Si substrate to a second depth on opposing sides of said gate, wherein said second depth is greater than said first depth, wherein laterally said second recession is spaced away from said channel by said spacer on both said opposing sides of said gate;
filling said second recession with a second epitaxial material, wherein said first and said second epitaxial materials are selected to have different lattice constants than said Si substrate, wherein a state of stress is imparted onto said channel; and
wherein said second epitaxial material and said first epitaxial material are being characterized as forming a source and a drain and their respective extensions for said FET device.

15. The method of claim 14, wherein said method further comprises selecting said FET device to be a PFET device, and selecting said first and said second epitaxial materials to contain Ge, wherein said state of stress imparted onto said channel is a compressive state of stress.

16. The method of claim 15, wherein said method further comprises selecting said first epitaxial material to have a Si content of between 0% and 95%, and correspondingly a Ge content between 100% and 5%.

17. The method of claim 14, wherein said method further comprises selecting said FET device to be an NFET device, and selecting said first and said second epitaxial materials to be SiC, wherein said state of stress imparted onto said channel is a tensile state of stress.

18. The method of claim 17, wherein said method further comprises selecting for said first epitaxial material a C content of between 0.1% and 20%.

19. The method of claim 14, wherein said method further comprises producing an offset spacer over said sidewalls prior of forming said first recession.

20. A method for fabricating a circuit structure, comprising:
defining at least one NFET portion and at least one PFET portion at a surface of a Si substrate;
masking said at least one NFET portion;
on said at least one PFET portion processing a PFET device such that said PFET device comprises a p-source and a p-drain that are each provided with a p-extension, wherein said p-extensions are mutually connected through a p-channel while respectively extending at said surface from said p-source and said p-drain towards said p-channel, wherein said p-source and said p-drain and said p-extensions each contain Ge, whereby having a larger lattice constant than said Si substrate, and due to said larger lattice constant said p-source and said p-drain and said p-extensions are imparting a compressive state of stress onto said p-channel;
masking said at least one PFET portion; and
on said at least one NFET portion processing an NFET device such that said NFET device comprises an n-source and an n-drain that are each provided with an n-extension, wherein said n-extensions are mutually connected through an n-channel while respectively extending at said surface from said n-source and said n-drain towards said n-channel, wherein said n-source and said n-drain and said n-extensions are composed of SiC having a smaller lattice constant than said Si substrate, whereby due to said smaller lattice constant said n-source and said n-drain and said n-extensions are imparting a tensile state of stress onto said n-channel.

21. The method of claim 20, wherein said method further comprises selecting said p-extensions to have a Si content of between 0% and 95%, and correspondingly a Ge content between 100% and 5%.

22. The method of claim 20, wherein said method further comprises selecting in said n-extensions said SiC to have a C content of between 0.1% and 20%.

23. The method of claim 20, wherein said method further comprises fabricating said circuit structure into a CMOS structure.
